(19) United States
(12) Patent Application Publication
(10) Pub. No.: US 2007/0127213 A1
(43) Pub. Date: Jun. 7, 2007

(54) Buckle structure

(75) Inventors: Yun-Hsiu Lee, Sanchong City (TW); Chun-San Lin, Taipei (TW); Yen-De Wu, Taipei (TW); Hung-Yuan Hung, Taipei (TW); Sun-Chen Yang, Taipei (TW)

Correspondence Address: BIRCH STEWART KOLASCH & BIRCH, PO BOX 747, FALLS CHURCH, VA, 22040-0747, US

(73) Assignees: AMCO TEC INTERNATIONAL INC.; ASUSTeK COMPUTER INC.

(21) Appl. No.: 11/542,173

(22) Filed: Oct. 4, 2006

(30) Foreign Application Priority Data
Dec. 7, 2005 (TW) 94143193

(51) Int. Cl. H05K 7/20

(52) U.S. Cl. 361/704

(57) ABSTRACT

The buckle includes a join region with two sidewalls. The ring body of the buckle is different thickness. The join region is formed in the thick ring body. When a hook of the heat sink is joined to this join region, the two sidewalls may limit the movement of the hook to fix the heat sink.

### RELATED APPLICATIONS

The present application is based on, and claims priority from, Taiwan Application Serial Number 94143193, filed Dec. 7, 2005, the disclosure of which is hereby incorporated by reference herein in its entirety.

### FIELD OF THE INVENTION

The present invention is related to a fixing apparatus, and more particularly to a fixing apparatus for fixing a heat sink.

### BACKGROUND OF THE INVENTION

With the increase in the operational processing speeds of semiconductor devices, metal pieces are installed over semiconductor devices to dissipate heat generated by the semiconductor devices and to reduce the operational temperature of the semiconductor devices to ensure they operate normally.

FIG. 1A illustrates a schematic diagram of a semiconductor device with a plurality of metal pieces installed on the semiconductor device to dissipate heat. A semiconductor device 102 is located on a motherboard 100. A heat sink 104 comprised of a plurality of metal pieces is installed over the semiconductor device 102 to dissipate the heat generated by the semiconductor device 102. A hook 106 installed in the heat sink 104 is joined to a buckle 108 for fixing this heat sink 104 over the semiconductor device 102.

However, as shown in the FIG. 1B, the bugle 108 has a smooth inner surface 1081. No bumps protrude out of the surface 1081. Therefore, the hook 106 can move along the inner surface 1081 when the motherboard 100 is shaken. The movement of the hook 106 also causes the movement of the heat sink 104. Any movement of the heat sink 104 may endanger other semiconductor devices installed on the motherboard 100 if the heat sink touches them.

Therefore, an improved buckle structure is needed.

### SUMMARY OF THE INVENTION

The main objective of the present invention is to provide a fixing apparatus to fix the heat sink.

The second objective of the present invention is to provide a buckle apparatus with an un-smooth inner surface to fix the hook.

The third objective of the present invention is to provide a buckle with a plurality of clasps formed by a mold. The clasps secure the buckle to the motherboard.

According to the foregoing purposes, the buckle comprises of a join region with two sidewalls. When the heat sink hook is connected to the join region, the two sidewalls may limit the movement of the hook and make it difficult to join the hook to the heat sink.

In one embodiment, the buckle comprises of a join region with two sidewalls. The ring body of the buckle is a different thickness. The join region is formed in the thick ring body. When a heat sink hook is joined to this join region, the two sidewalls may limit the movement of the hook and make it difficult to join the hook to the heat sink.

In another embodiment, the fixing apparatus of the present invention comprises of a plurality of buckles and an elastic clasp to fix a heat sink. The buckle is formed by a mold. The buckle comprises of a join region, a pair of clasps extended from the region of the buckle opposite to the join region and bumps are formed in the side of the buckle. The two clasps are separated and symmetrical to a trench. Each clasp has a hook facing out. When the buckle is installed on a motherboard, the buckle is fixed to the motherboard with the hooks. The distance between the hook and the bending region is equal to the thickness of the motherboard.

### BRIEF DESCRIPTION OF THE DRAWINGS

The foregoing aspects and many of the attendant advantages of this invention are more readily appreciated and better understood by referencing the following detailed description, when taken in conjunction with the accompanying drawings, wherein:

FIG. 1A is a schematic diagram of a semiconductor device with a heat sink thereon.

FIG. 1B is an enlarged diagram of a typical buckle structure.

FIG. 2A and FIG. 2B respectively illustrate a buckle structure according to a preferred embodiment of the present invention.

FIG. 3 is a schematic diagram of a semiconductor device with a heat sink thereon according to a preferred embodiment of the present invention. FIG. 4A illustrates a triangle shape buckle according to a preferred embodiment of the present invention.

FIG. 4B illustrates a reversed hopper shape buckle according to a preferred embodiment of the present invention.

FIG. 5 illustrates a buckle structure according to another preferred embodiment of the present invention.

FIG. 6 is a schematic diagram of a semiconductor device with a heat sink thereon according to another preferred embodiment of the present invention.

FIG. 7 is a schematic diagram of a fixing apparatus of the present invention.

FIG. 8 illustrates the apparatus securing a heat sink onto a motherboard according to the present invention.

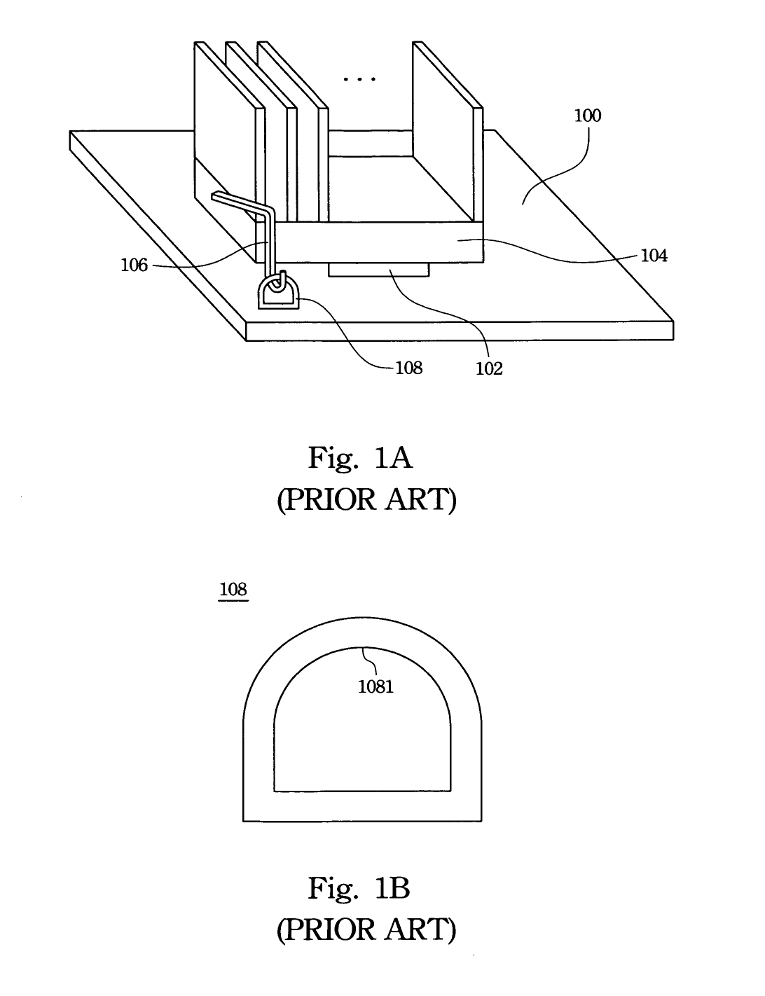

### DETAILED DESCRIPTION OF THE PREFERRED EMBODIMENT

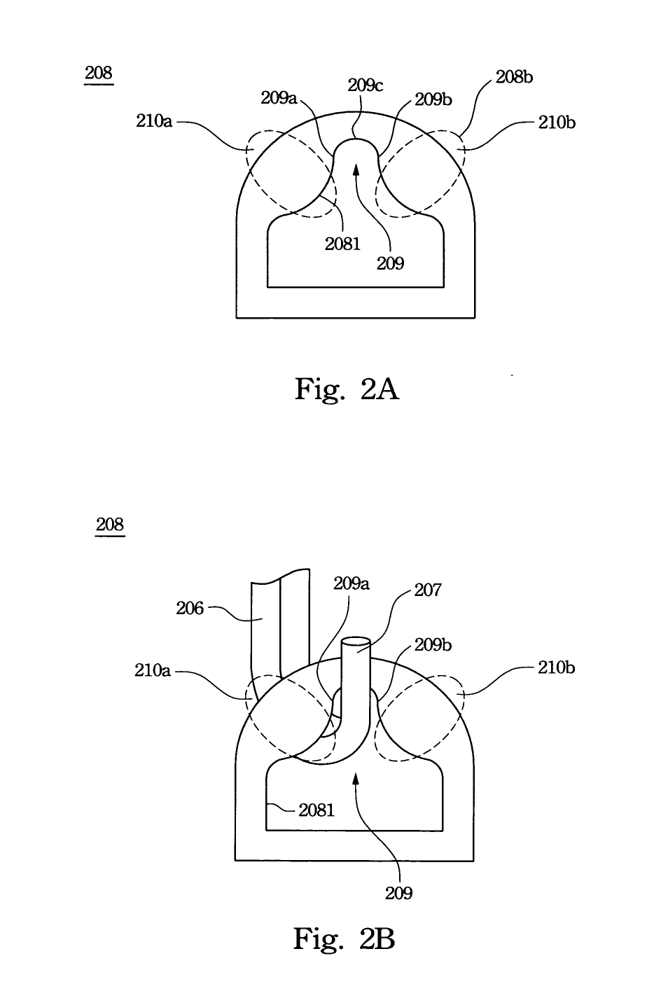

FIG. 2A illustrates a buckle structure according to a preferred embodiment of the present invention. The buckle is in the shape of a half-ellipse. In FIG. 2A, a join region 209 is formed on the inner surface 2081 of buckle 208. The join region 209 is similar to a trench and has two sidewalls 209a and 209b and a top part 209c.

In FIG. 2B, a clasp 206 has a hook 207. When joining, the hook 206 engages the join region 209. The two sidewalls 209a and 209b may limit the movement of the hook 206 to fix the clasp 206. The width of the top part 209c and the height of the sidewalls 209a and 209c are designed to fit the hook 207.

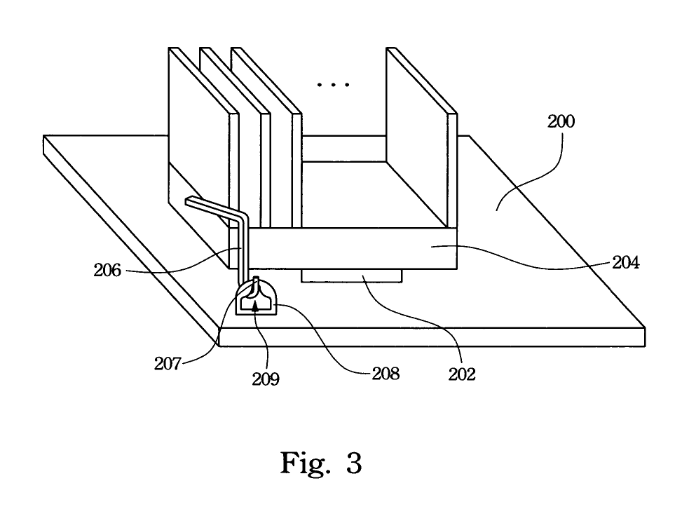

On the other hand, to enhance the joining mechanical strength, the ring body of the sidewalls 209a and 209c of the buckle are enlarged to form a thicker ring body 210a and 210b. In other words, the ring body of the buckle is a different thickness. Moreover, the buckle 208 has an inner surface 2081 that is inclined toward the top part 209c. Therefore, when the clasp 206 is joined to the buckle 208, the hook 207 may automatically move along the inner surface 2081 to the top part 209c of the join region 209. FIG. 3 is a schematic diagram of a semiconductor device with a heat sink thereon according to a preferred embodiment of the present invention. A fin-type heat sink 204 is installed over a semiconductor device 202 on a motherboard 200. The clasp 206 is joined with the buckle 208 of the present invention. The hook 207 of the clasp 206 is limitted in the join region 209 of the buckle 208. Other heat sink types are also used in the present invention.

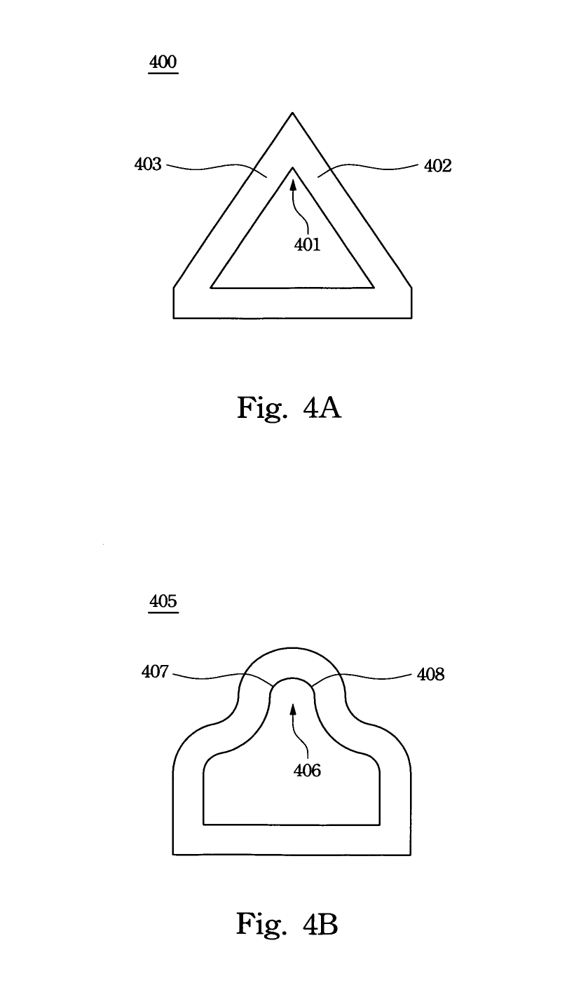

Moreover, the shape of the buckle 400 is trianglular as shown in the FIG. 4A. When joining, the hook 207 of the clasp 206 is joined with the join region 401. The two sidewalls 402 and 403 of the join region 401 may limit the movement of the clasp 206. FIG. 4B illustrates a reversed hopper shape buckle 405 according to another embodiment. When joining, the hook 207 of the clasp 206 is joined with the join region 406. The two sidewalls 407 and 408 of the join region 406 may limit the movement of the clasp 206. It is noticed that the present invention may be implemented with any buckle shape to form a join region with two sidewalls.

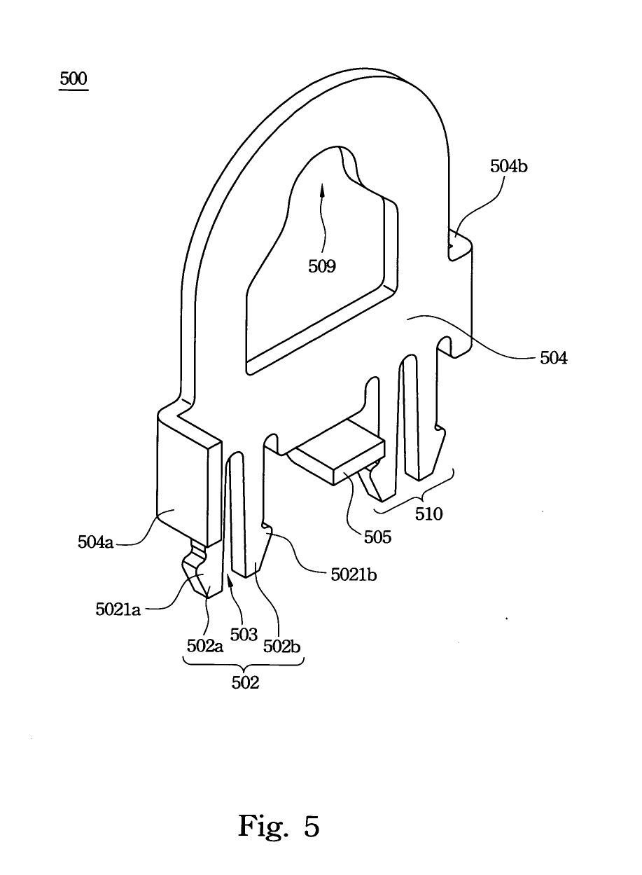

FIG. 5 illustrates a buckle structure according to another preferred embodiment of the present invention. In this embodiment, two elastic join means 502 and 510 are formed in the buckle 500. The buckle 500 is fixed to a motherboard by the two elastic join means 502 and 510 that connect to the motherboard. In this embodiment, a join region 509 is formed in the inner surface of the buckle 500. The two join means 502 and 510 are extended from the region opposite to the join region 509 of the buckle 500. Each elastic join means, such as the join means 502, includes a pair of clasps 502a and 502b. A trench 503 isolates the two clasps 502a and 502b. The clasp 502a has a hook 5021a. The clasp 502b has a hook 5021b. The two clasps 502a and 502b are symmetric to each other. Moreover, the bottom part 504 of the buckle 500 is bent to form two bent parts 504a and 504b. The distance between the hook 5021a and the bent part 504a is equal to the thickness of a corresponding motherboard. On the other hand, a bump 505 is formed in the bottom part 504. When the buckle 500 is joined to a motherboard, the bump 505 is in contact with the motherboard. The buckle 500 can be formed with a mold.

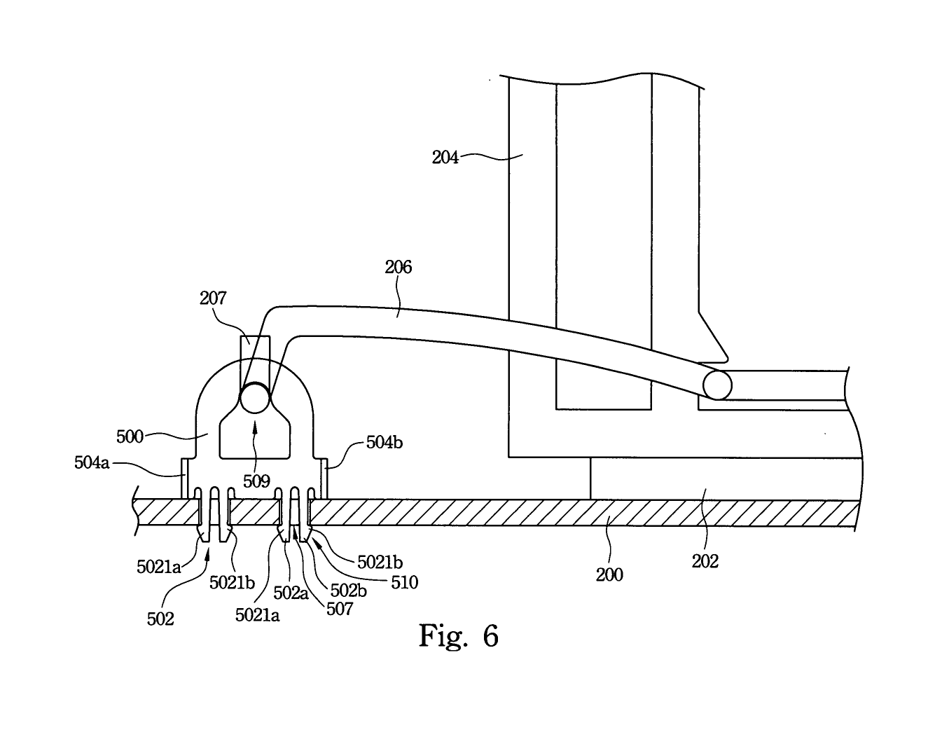

FIG. 6 is a schematic diagram of a semiconductor device with a heat sink thereon according to another preferred embodiment of the present invention. In this figure, the join means 502 and 510 are respectively inserted into corresponding holes 507. The bent parts 504 touch the front side of the motherboard 200. The hooks 5021a and 5021b touch the backside of the motherboard 200. The distance between the hook 5021a and the bent part 504a is equal to the thickness of the motherboard 200. The hook 207 of the clasp 206 is joined with the join region 509 of the buckle 500. Accordingly, the buckle 500 is formed with a mold. Therefore, the buckle 500 has a fixed size. In other words, the buckle 500 may be produced on a large scale. Moreover, the buckle 500 can be easily installed onto the motherboard 200 by the two join means 502 and 510. On the other hand, the hook 207 of the clasp 206 is limited to the join region 207 of the buckle 500. Therefore, the heat sink 204 can be securely fixed over the semiconductor device 202.

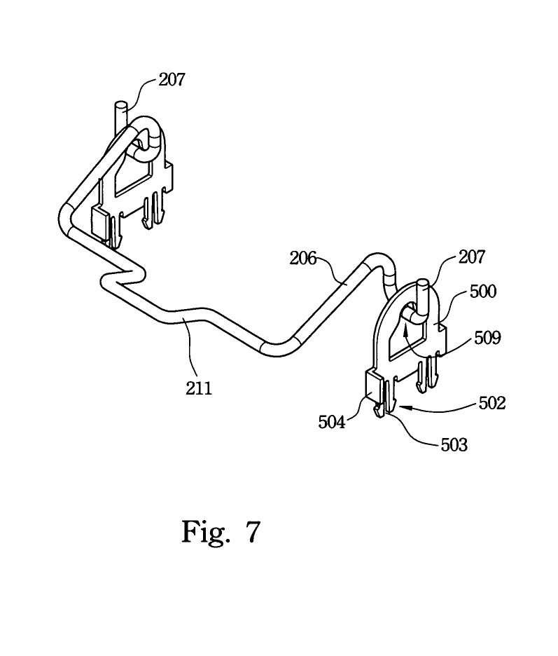

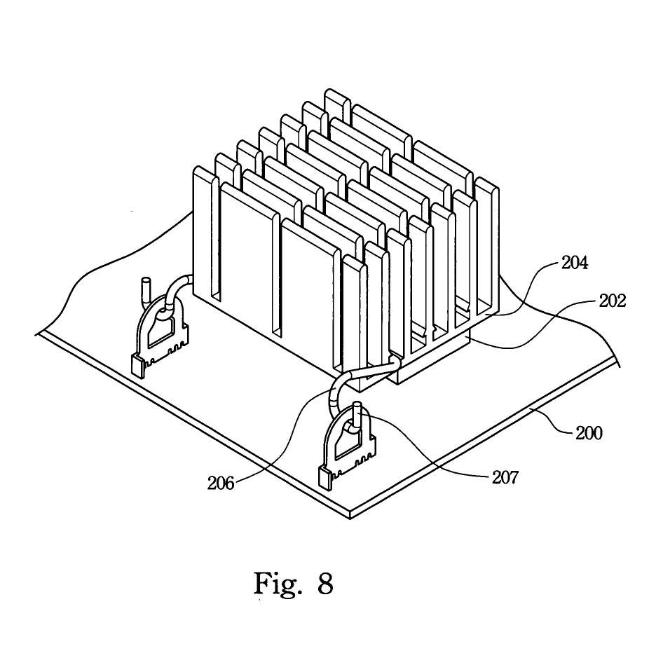

FIG. 7 illustrates a schematic diagram of a fixing apparatus according to the present invention. A metal rod is bent to form the clasp 206. The two ends of the metal rod are bent up to form hook 207. The center part of the metal rod is bent out to form the coupler 211. According to the present invention, the coupler part 211 is raised at an angle. When in use securing the heat sink, as shown in the FIG. 8, the raised coupler 211 may provide a force to press the heat sink 204 down over the semiconductor device 202. It is noticed that the clasp 207 may be designed to form other type.

Accordingly, the buckle of the present invention includes a join region with two sidewalls. When a hook of the heat sink is joined to this join region, the two sidewalls may limit the movement of the hook to fix the heat sink. In other words, a join region is especially formed in the buckle. The join region size depends on the hook so that the hook will have limited movement.

As is understood by a person skilled in the art, the foregoing descriptions of the preferred embodiment of the present invention are an illustration of the present invention rather than a limitation thereof. Various modifications and similar arrangements are included within the spirit and scope of the appended claims. The scope of the claims should be accorded to the broadest interpretation so as to encompass all such modifications and similar structures. While preferred embodiments of the invention have been illustrated and described, it will be appreciated that various changes can be made therein without departing from the spirit and scope of the invention.

What is claimed is:

1. A buckle structure located on a motherboard to join with the join means of a heat sink, comprising:
a ring body; and
a trench formed in an inner surface of said ring body, when said join means joins with said trench, said join means is located in said trench to limit said join means movement.

2. The buckle structure of claim 1, wherein when said join means joins with said trench, said join means is connected to the top end of said trench.

3. The buckle structure of claim 1, wherein said heat sink is located over a semiconductor device.

4. The buckle structure of claim 1, wherein said ring body has a half-ellipse shape.

5. The buckle structure of claim 1, wherein said ring body has a reversed hopper shape.

6. The buckle structure of claim 1, wherein said ring body has different thickness.

7. The buckle structure of claim 6, wherein said trench is located in a thick position of said ring body.

8. The buckle structure of claim 1, wherein said structure further comprises two join means extended from said buckle, each join means includes two clasps symmetrical to a trench and each clasp has a hook facing out.

9. The buckle structure of claim 8, wherein said structure further comprises at least one bent part extended from said ring body.

10. The buckle structure of claim 9, wherein a distance between said bent part and said hook is equal to said motherboard thickness.

11. The buckle structure of claim 1, wherein said join means is made by a metal, wherein two ends of said metal are bent up to form two hooks, and center part of said metal is bent out to form a coupler, said coupler is raised at an angle.

12. A buckle structure located on a motherboard to join with a join means of a heat sink, comprising:
a ring body, wherein said ring body includes at least two, first and second, regions that are thicker than other regions of said ring body; and
a trench formed between said first and second regions, when said join means joins with said trench, said join means is located in said trench to limit said join means movement.

13. The buckle structure of claim 12, wherein when said trench size is larger than said join means.

14. The buckle structure of claim 12, wherein said heat sink is located over a semiconductor device.

15. The buckle structure of claim 12, wherein said ring body has a half-ellipse shape.

16. The buckle structure of claim 12, wherein said ring body has a reversed hopper shape.

17. The buckle structure of claim 12, wherein said structure further comprises two join means extended from said buckle, each join means includes two clasps symmetrical to a trench and each clasp has a hook facing out.

18. The buckle structure of claim 17, wherein said structure further comprises at least one bent part extended from said ring body.

19. The buckle structure of claim 18, wherein a distance between said bent part and said hook is equal to said motherboard thickness.

20. The buckle structure of claim 1, wherein said join means is made by a metal, wherein two ends of said metal are bent up to form two hooks, and the center part of said metal is bent out to form a coupler, said coupler is raised at an a angle.
